(19) United States
(12) Patent Application Publication
(10) Pub. No.: US 2009/0180259 A1
(43) Pub. Date: Jul. 16, 2009

(54) PORTABLE MEDIA PLAYER

(75) Inventor: Juen Tien Peng, Shenzhen (CN)

Correspondence Address: MORRIS MANNING MARTIN LLP, 3343 PEACHTREE ROAD, NE, 1600 ATLANTA FINANCIAL CENTER, ATLANTA, GA, 30326, US

(73) Assignee: ACTION TECHNOLOGY (SZ) CO., LTD., Shenzhen (CN)

(21) Appl. No.: 12/013,681

(22) Filed: Jan. 14, 2008

(51) Int. Cl. H05K 7/00

(52) U.S. Cl. 361/729

(57) ABSTRACT

The invention discloses a portable media player for playing DVD and IPOD including a base (1) defining a first docking bay (3) for a DVD host and a second docking bay (4) for a IPOD, a cover (2) with a display attached to the base, and a locking device (5) attached at the base for obstructing the detachment of the IPOD. The locking device includes a through hole (7), a resilient piece (8), and a protruding member (9). The base has a rotating shaft (6) and a groove (10). When the resilient piece is engaged into the groove, the protruding member is adjacent to the IPOD and obstructs the detachment of the IPOD.

### FIELD OF THE INVENTION

The present invention relates generally to medial players. More particularly, the invention relates to a portable media player with attachable and detachable DVD host and IPOD.

### BACKGROUND OF THE INVENTION

With rapid development of science and technologies, more and more convenience is brought into mankind lives. Portable media player is one of productions of modern industries for entertainment. Some portable media players integrate various portable entertainment devices, such as DVD player and IPOD. They are small, exquisite, and have fashion appearance designs and large storage functions. However, in present design, technology for docking IPOD into the potable media player has not good structure and is not tight enough, which needs to be improved for better performance.

### SUMMARY OF THE INVENTION

The purpose of the present invention is to provide a portable media player with attachable and detachable DVD host and IPOD.

One embodiment of the present invention provides a portable media player, which comprises a base and a cover attached to each other by a hinge. A first docking bay configured to accommodate a DVD host is defined into the base. A second docking bay configured to accommodate an IPOD is defined into the base. The DVD host and the IPOD are accommodated into the base via the first docking bay and the second docking bay respectively. A display is assembled onto an inner side of cover. A locking device is attached at the base beside one side of the IPOD. A through hole is defined into one distal end of the locking device. A rotating shaft corresponding to the through hole is assembled at the base. The locking device is pivotally assembled at the base when the rotating shaft is engaged into the through hole. A resilient piece and a protruding member extend from another end of the locking device. A groove corresponding to the resilient piece is defined in the base. When the resilient piece is engaged into the groove, the protruding member is adjacent to the IPOD and obstructs the detachment of the IPOD.

In another preferred embodiment, the locking device may be assembled at the base beside another edge of the second docking bay for IPOD.

In another preferred embodiment, a pair of locking devices may be assembled at the base beside any two edges of the second docking bay respectively.

In another preferred embodiment, three locking devices may be assembled at the base beside any three edges of the second docking bay respectively.

In another preferred embodiment, four locking devices may be assembled at the base beside four edges of the second docking bay respectively.

The portable media player in accordance with the present invention has a locking device for IPOD, which has simple structure and smart design, can safeguard IPOD in the portable media player, and prevent it from accidental detachment because of collision and shaking, consequently, which renders the portable media player better playing effect and better safe performance.

### BRIEF DESCRIPTION OF THE DRAWINGS

FIG. 1 is a perspective view of a portable media player in accordance with the present invention, with a locking device in an open position;

FIG. 2 is a perspective view of the locking device in the portable media player in accordance with the present invention; and

FIG. 3 is a perspective view of the portable media player in accordance with the present invention, with the locking device in a close position.

### DETAILED DESCRIPTION OF THE INVENTION

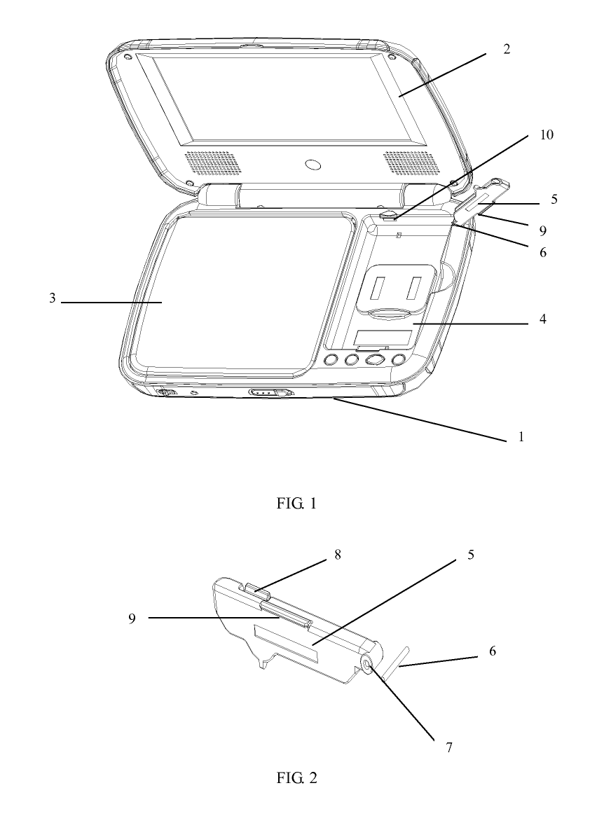

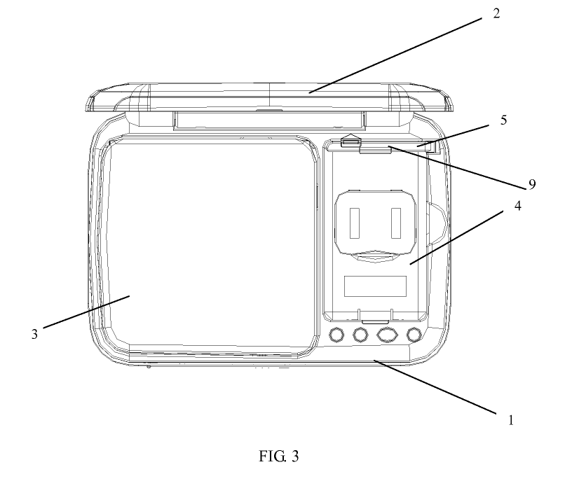

Referring to FIG. 1 and FIG. 2, a portable media player in accordance with the present invention comprises a base 1 and a cover 2 attached to each other by a hinge. A first docking bay 3 configured to accommodate a DVD host is defined into the base 1. A second docking bay 4 configured to accommodate an IPOD is defined into the base 1. The DVD host and the IPOD are accommodated into the base 1 via the first docking bay 3 and the second docking bay 4 respectively. A display is assembled on an inner side of the cover 2. A locking device 5 is attached at the base 1 beside the IPOD. A through hole 7 is defined into one distal end of the locking device 5. A rotating shaft 6 corresponding to the through hole 7 is assembled at the base 1. The locking device 5 is pivotally assembled at the base 1 when the rotating shaft 6 is engaged into the through hole 7. A resilient piece 8 and a protruding member 9 extend from another end of the locking device 5. A groove 10 corresponding to the resilient piece 8 is defined in the base 10. When the resilient piece 8 is engaged into the groove 10, the protruding member 9 is adjacent to the IPOD and obstructs the detachment of the IPOD.

In another preferred embodiment, the locking device 5 may be assembled at the base 1 beside another edge of the second docking bay 4 for IPOD.

In another preferred embodiment, a pair of locking devices 5 may be assembled at the base 1 beside any two edges of the second docking bay 4 respectively.

In another preferred embodiment, three locking devices 5 may be assembled at the base 1 beside any three edges of the second docking bay 4 respectively.

In another preferred embodiment, four locking devices 5 may be assembled at the base 1 beside four edges of the second docking bay 4 respectively.

What is claimed is:

1. A portable media player for playing DVD and IPOD, comprising:
a base defining a first docking bay for a DVD host and a second docking bay for a IPOD,
a cover with a display attached to the base, and
a locking device attached at the base beside the second docking bay for obstructing the detachment of the IPOD.

2. The portable media player as claimed in claim 1, wherein a through hole is defined into one end of the locking device, a rotating shaft corresponding to the through hole is assembled at the base, the locking device is pivotally assembled at the base when the rotating shaft is engaged into the through hole, a resilient piece and a protruding member extend from another end of the locking device, a groove corresponding to the resilient piece is defined in the base, and when the resilient piece is engaged into the groove, the protruding member is adjacent to the IPOD and obstructs the detachment of the IPOD.

3. The portable media player as claimed in claim 1, wherein the locking device is attached at the base beside any edge of the second docking bay.

4. The portable media player as claimed in claim 1, wherein a pair of locking devices is assembled at the base beside two edges of the second docking bay respectively.

5. The portable media player as claimed in claim 1, wherein three locking devices are assembled at the base beside three edges of the second docking bay respectively.

6. The portable media player as claimed in claim 1, wherein four locking devices are assembled at the base beside four edges of the second docking bay respectively.

7. A portable media player for playing entertainment devices, comprising:
a base defining at least one docking bay for at least one entertainment device,
a cover with a display attached to the base, and
at least one locking device attached at the base beside at least one edge of the at least one docking bay for obstructing the detachment of the entertainment device.

8. The portable media player as claimed in claim 7, wherein a through hole is defined into one end of the at least one locking device, a rotating shaft corresponding to the through hole is assembled at the base, the at least one locking device is pivotally assembled at the base when the rotating shaft is engaged into the through hole, a resilient piece and a protruding member extend from another end of the at least one locking device, a groove corresponding to the resilient piece is defined in the base, and when the resilient piece is engaged into the groove, the protruding member is adjacent to the entertainment device and obstructs the detachment of the entertainment device.

9. The portable media player as claimed in claim 7, wherein the at least one entertainment device is an IPOD.
